(19) United States
(12) Patent Application Publication
(10) Pub. No.: US 2025/0022822 A1
(43) Pub. Date: Jan. 16, 2025

(54) SEMICONDUCTOR ELEMENT AND SEMICONDUCTOR DEVICE

(71) Applicant: ROHM CO., LTD., Kyoto-shi (JP)

(72) Inventor: Hirofumi TANAKA, Kyoto-shi (JP)

(21) Appl. No.: 18/899,816

(22) Filed: Sep. 27, 2024

Related U.S. Application Data
(63) Continuation of application No. PCT/JP2023/011189, filed on Mar. 22, 2023.

(30) Foreign Application Priority Data
Mar. 31, 2022 (JP) 2022-058713

(51) Int. Cl. H01L 23/00; H01L 23/31

(52) U.S. Cl. CPC H01L 24/05; H01L 23/3107; H01L 24/32; H01L 24/45; H01L 24/48; H01L 24/73; H01L 2224/04042; H01L 2224/05015; H01L 2224/0508; H01L 2224/05124; H01L 2224/05144; H01L 2224/05155; H01L 2224/05164; H01L 2224/05166; H01L 2224/05184; H01L 2224/32245; H01L 2224/45147; H01L 2224/48175; H01L 2224/73265; H01L 2924/0132; H01L 2924/04941; H01L 2924/07025; H01L 2924/3512

(57) ABSTRACT

A semiconductor element includes: an element body including an obverse surface facing a first side in a thickness direction z; a wiring layer formed on the obverse surface and electrically connected to the element body; an insulating layer covering the obverse surface and the wiring layer, and including a first opening overlapping with the wiring layer as viewed in the thickness direction z; a surface protection film covering the insulating layer, and including a second opening overlapping with the wiring layer and the first opening as viewed in the thickness direction z; a metal layer overlapping with the first opening and the second opening, and also overlapping with the surface protection film as viewed in the thickness direction, and a mitigation layer (underlying layer) provided between the wiring layer and the metal layer. A first material of the mitigation layer is less affected by an orientation of the wiring layer than a second material of a portion of the metal layer located closest to the wiring layer.

### TECHNICAL FIELD

The present disclosure relates to a semiconductor element and a semiconductor device.

### BACKGROUND ART

Semiconductor elements configured with switching circuits, such as metal-oxide-semiconductor field-effect transistors (MOSFETs) or insulated gate bipolar transistors (IGBTs), have been used for current control in various industrial apparatuses and vehicles. For example, JP-A-2020-77680 discloses an example of such a semiconductor element.

The semiconductor element includes a semiconductor substrate, a semiconductor layer, an interlayer insulating film, a wiring layer, a passivation film, an electrode, and a surface protection film. The semiconductor layer, the interlayer insulating film, the wiring layer, and the passivation film are formed on the semiconductor substrate, and the electrode, which is electrically connected to the wiring layer, is provided in a recess in the passivation film. The surface protection film covers the passivation film, and is formed with an opening that exposes the electrode. The wiring layer and the electrode mainly contain Al. When a bonding wire containing Cu is bonded to the semiconductor element, the semiconductor layer may crack, or corrosion may occur at the boundary between the electrode and the bonding wire, causing a bonding failure of the bonding wire. To solve these problems, a semiconductor element has been developed in which a metal layer (including a Ni layer, for example) is formed instead of the electrode. The metal layer is electrically connected to the wiring layer and partially overlaps with a surface of the surface protection film, and is used as a pad for bonding the bonding wire.

### BRIEF DESCRIPTION OF THE DRAWINGS

FIG. 1 is a perspective view showing a semiconductor device according to a first embodiment of the present disclosure.

FIG. 2 is a plan view showing the semiconductor device of FIG. 1, as seen through a sealing resin.

FIG. 3 is a bottom view showing the semiconductor device of FIG. 1.

FIG. 4 is a front view showing the semiconductor device of FIG. 1.

FIG. 5 is a right-side view showing the semiconductor device of FIG. 1.

FIG. 6 is a cross-sectional view along line VI-VI in FIG. 2.

FIG. 7 is a cross-sectional view along line VII-VII in FIG. 2.

FIG. 8 is a plan view showing a semiconductor element according to the first embodiment.

FIG. 9 is a partially enlarged view of FIG. 8, showing a part around a metal layer.

FIG. 10 is a cross-sectional view along line X-X in FIG. 9.

FIG. 11 is a partially enlarged cross-sectional view showing a semiconductor element according to a second embodiment of the present disclosure.

FIG. 12 is a partially enlarged plan view showing a semiconductor element according to a third embodiment of the present disclosure.

FIG. 13 is a cross-sectional view along line XIII-XIII in FIG. 12.

FIG. 14 is a partially enlarged plan view showing a semiconductor element according to a fourth embodiment of the present disclosure.

### DETAILED DESCRIPTION OF EMBODIMENTS

The following describes preferred embodiments of a semiconductor element and a semiconductor device according to the present disclosure with reference to the drawings. In the following description, identical or similar elements are provided with the same reference numerals, and descriptions thereof are omitted. The terms such as “first”, “second” and “third” in the present disclosure are used merely as labels and not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”. Further, the phrase “an object A (or the material thereof) contains a material C” includes “an object A (or the material thereof) is made of a material C” and “an object A (or the material thereof) is mainly composed of a material C”.

### First Embodiment

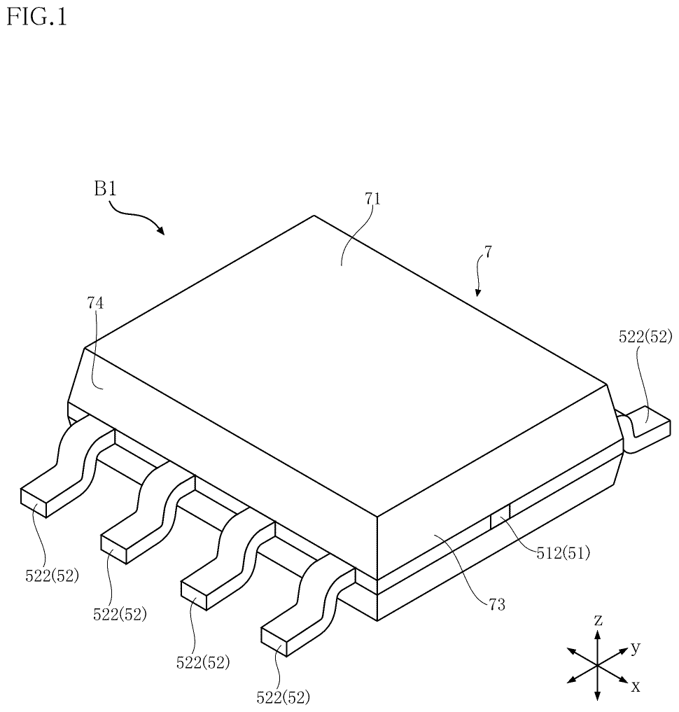

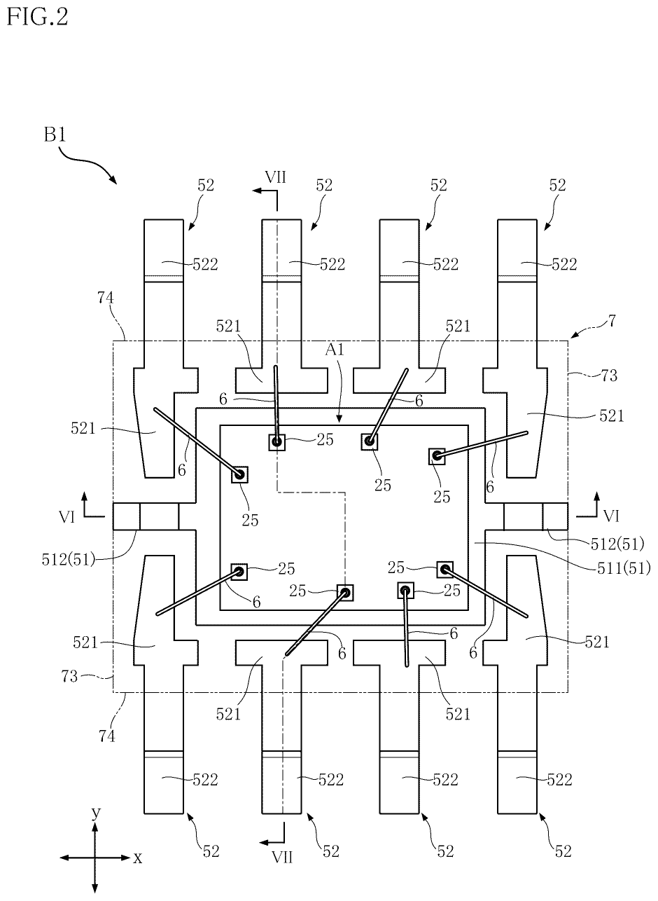

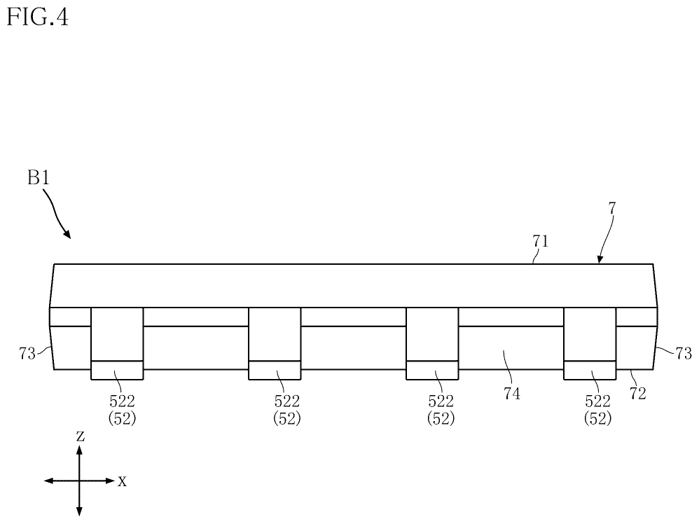

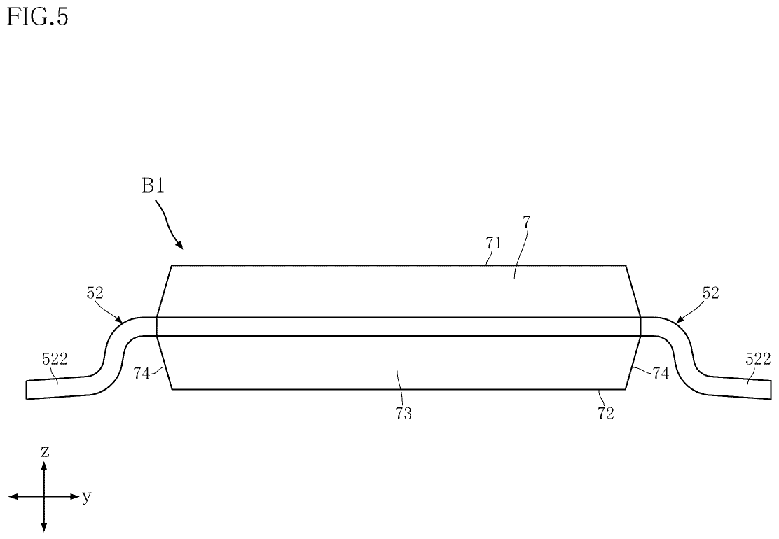

FIGS. 1 to 10 show a semiconductor element A1 according to a first embodiment and a semiconductor device B1 including the semiconductor element A1. For convenience of understanding, FIG. 2 shows a sealing resin 7 in phantom, and the outer shape of the sealing resin 7 is indicated by an imaginary line (two-dot chain line). As shown in these figures, the semiconductor device B1 includes the semiconductor element A1, a first lead 51, a plurality of second leads 52, a plurality of connecting members 6, and a sealing resin 7. The semiconductor device B1 is configured by modularizing the semiconductor element A1. The shape and size of the semiconductor device B1 are not particularly limited.

For convenience of description, the thickness direction of the semiconductor device B1 is referred to as “thickness direction z”. In the following description, one side in the thickness direction z may be referred to as “upward”, and the other side as “downward”. Note that the terms such as “top”, “bottom”, “upward”, “downward”, “upper surface”, and “lower surface” are used to indicate the relative positions of components or the like in the thickness direction z and do not necessarily define the relationship with respect to the direction of gravity. Also, “plan view” refers to the view seen in the thickness direction z. A direction perpendicular to the thickness direction z is referred to as “first direction x”. The first direction x is the horizontal direction in the plan view (see FIG. 2) of the semiconductor device B1. The direction perpendicular to the thickness direction z and the first direction x is referred to as “second direction y”. The second direction y is the vertical direction in the plan view (see FIG. 2) of the semiconductor device B1.

The semiconductor element A1 is an element that exerts an electrical function of the semiconductor device B1. In the present embodiment, the semiconductor element A1 is, for example, a bipolar CMOS DMOS (BiCDMOS) element, which is a semiconductor composite element in which a bipolar element, a complementary MOS (CMOS) transistor, and a double diffusion MOS (DMOS) transistor are formed on a common semiconductor substrate. Note that the semiconductor element A1 is not limited to a particular element.

As shown in FIGS. 2, 6 and 7, the semiconductor element A1 is mounted on the first lead 51. The semiconductor element A1 includes an element body 10, an insulating layer 13, a wiring layer 14, a reverse-surface electrode 24, a plurality of metal layers 25, a plurality of underlying layers 21, and a surface protection film 26.

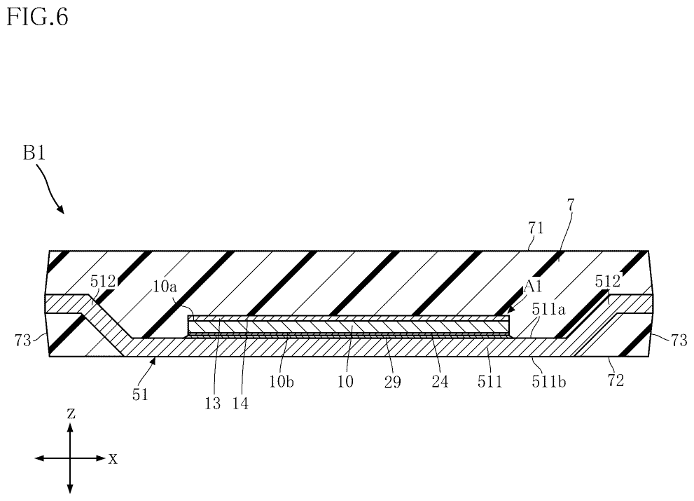

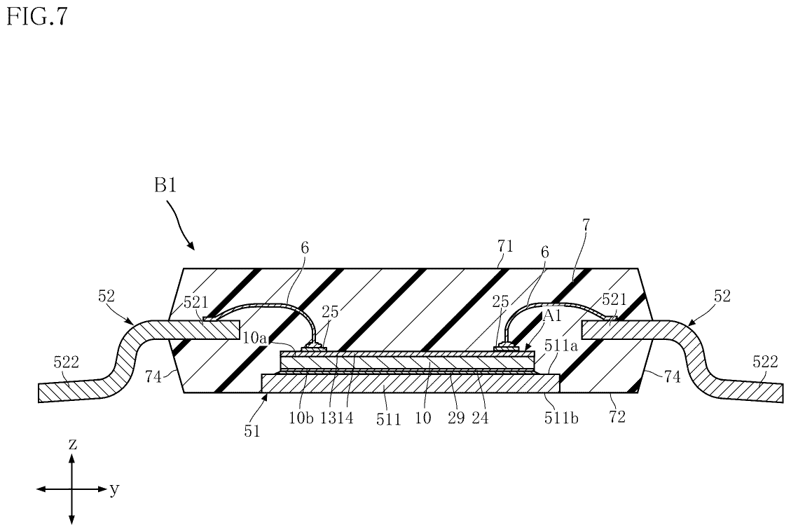

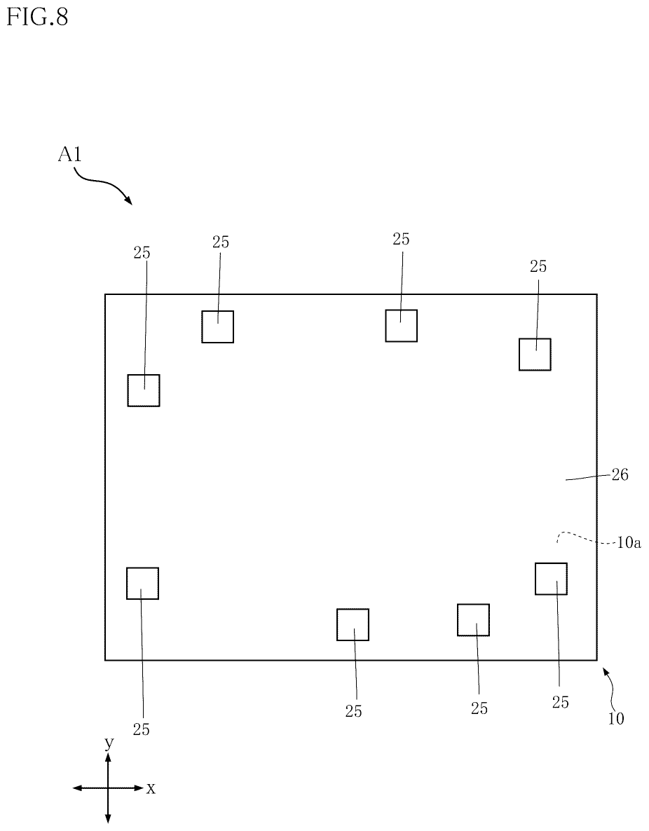

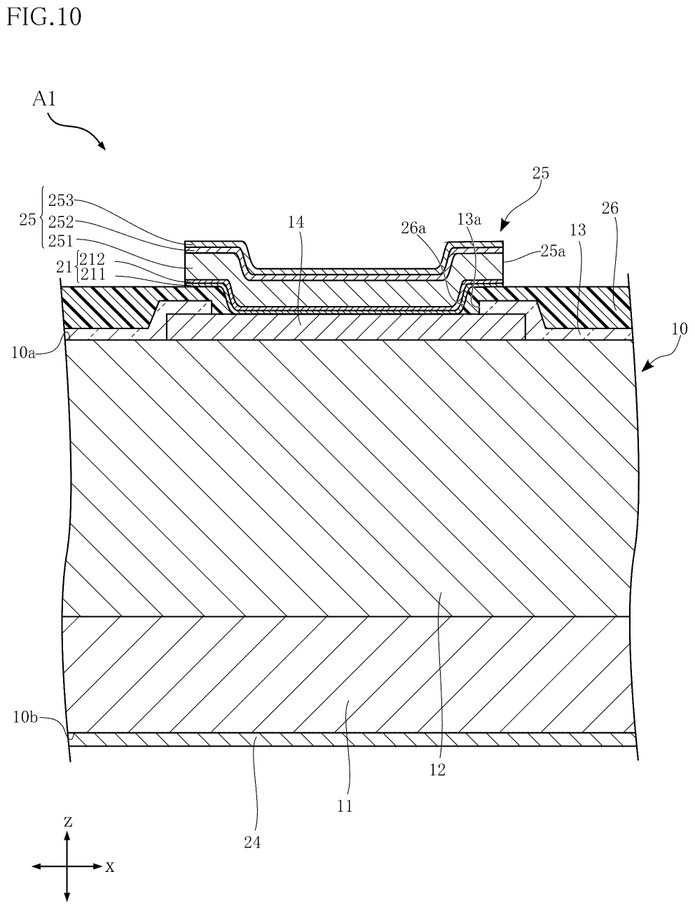

As shown in FIGS. 2 and 8, the element body 10 has a rectangular shape in plan view. As shown in FIGS. 6 and 7, the element body 10 has an obverse surface 10a and a reverse surface 10b. The obverse surface 10a faces a first side in the thickness direction z. The reverse surface 10b faces the opposite side from the obverse surface 10a. As shown in FIG. 10, the element body 10 includes a semiconductor substrate 11 and a semiconductor layer 12.

The semiconductor substrate 11 supports the semiconductor layer 12. The semiconductor substrate 11 is an n+ semiconductor layer. The semiconductor substrate 11 contains silicon (Si) or silicon carbide (SiC), for example. The semiconductor layer 12 is formed on the semiconductor substrate 11. The semiconductor layer 12 is electrically connected to the semiconductor substrate 11. The surface (the lower surface in FIG. 10) of the semiconductor substrate 11 facing the opposite side from the surface on which the semiconductor layer 12 is formed is the reverse surface 10b of the element body 10. The surface (the upper surface in FIG. 10) of the semiconductor layer 12 facing the opposite side from where the semiconductor substrate 11 is located in the thickness direction z is the obverse surface 10a of the element body 10.

The wiring layer 14 is formed on the obverse surface 10a, and is electrically connected to the semiconductor layer 12 of the element body 10. The wiring layer 14 is made of an alloy (AlCu) formed by adding a small amount of copper (Cu) to aluminum (Al). Note that the material of the wiring layer 14 is not particularly limited to AlCu, and may be another material containing Al, such as AlSi, or may be Al, which is a pure metal rather than an alloy. The wiring layer 14 is formed by sputtering, for example. Note that the method for forming the wiring layer 14 is not particularly limited. The plan-view shape of the wiring layer 14 is not particularly limited, and can be designed appropriately according to the arrangement position of each circuit in the semiconductor layer 12 and the arrangement position of the metal layers 25. The wiring layer 14 mainly contains Al, and thus has an orientation based on the crystal structure of Al.

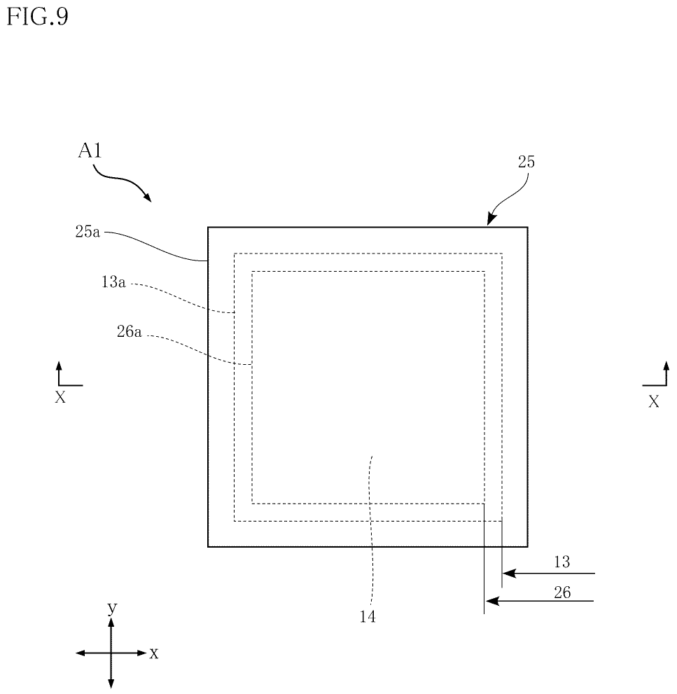

The insulating layer 13 is formed on the obverse surface 10a, and covers the obverse surface 10a and the wiring layer 14. The insulating layer 13 is electrically insulative, and is made of a silicon oxide (SiO₂) film and a silicon nitride (Si₃N₄) film formed on the silicon oxide film, for example. The insulating layer 13 is formed by plasma chemical vapor deposition (CVD), for example. Note that the configuration, material, and formation method of the insulating layer 13 are not particularly limited. The insulating layer 13 has a plurality of openings 13a that pass through the insulating layer 13 in the thickness direction z. The openings 13a expose the wiring layer 14. As shown in FIG. 9, each of the openings 13a in the present embodiment has a rectangular shape as viewed in the thickness direction z.

FIG. 10 shows only the uppermost wiring layer 14 for simplification, but it is possible to form a plurality of wiring layers 14. In this case, an interlayer insulating layer is provided between the wiring layers 14, and the wiring layers 14 are electrically connected to each other through a via formed in the interlayer insulating layer.

The surface protection film 26 is formed on the obverse surface 10a, and covers the insulating layer 13. In the present embodiment, the surface protection film 26 covers the inner edges of the openings 13a of the insulating layer 13, and is in contact with the wiring layer 14. The surface protection film 26 is electrically insulative, and contains polyimide resin, for example. Note that the material of the surface protection film 26 is not particularly limited, and may be another insulating material. The surface protection film 26 has a plurality of openings 26a that pass through the surface protection film 26 in the thickness direction z. The openings 26a expose the wiring layer 14. As shown in FIG. 9, each of the openings 26a in the present embodiment has a rectangular shape as viewed in the thickness direction z, and the shape is similar to the shape of each of the openings 13a as viewed in the thickness direction z. In the present embodiment, the openings 26a are enclosed by the respective openings 13a as viewed in the thickness direction z. The surface protection film 26 is formed by applying a photosensitive resin material with a spin coater, followed by photolithography, for example. Note that the method for forming the surface protection film 26 is not particularly limited.

Each of the metal layers 25 is formed on the wiring layer 14, and overlaps with an opening 13a of the insulating layer 13 and an opening 26a of the surface protection film 26 as viewed in the thickness direction z. Each of the metal layers 25 is electrically connected to an internal circuit of the semiconductor layer 12 via an underlying layer 21 and the wiring layer 14. As viewed in the thickness direction z, each of the metal layers 25 overlaps with a portion of the surface protection film 26. As shown in FIG. 2, the metal layers 25 function as pads to which the connecting members 6 are bonded. Each of the metal layers 25 is provided to prevent problems that may occur when a bonding wire is directly bonded to the wiring layer 14, and such problems may be cracks in the element body 10, corrosion at the boundary between the wiring layer 14 and the bonding wire, and a bonding failure of the bonding wire, for example.

As shown in FIG. 10, each of the metal layers 25 is made up of a plurality of metal layers stacked on each other, and includes a first layer 251, a second layer 252, and a third layer 253. The first layer 251 is located closest to the wiring layer 14 out of the first layer 251, the second layer 252, and the third layer 253, and contains Ni. The second layer 252 is in contact with the first layer 251 and contains Pd. The third layer 253 is in contact with the second layer 252 and contains Au. The first layer 251, the second layer 252, and the third layer 253 are formed by electroplating. Note that the configuration, material, and formation method of each of the first layer 251, the second layer 252, and the third layer 253 are not particularly limited. For example, each of the metal layers 25 may not include a third layer 253.

As shown in FIG. 9, each of the metal layers 25 in the present embodiment has a rectangular shape as viewed in the thickness direction z, and the shape is similar to the shape of each of the openings 13a as viewed in the thickness direction z. In the present embodiment, the openings 13a and the openings 26a are enclosed by the respective metal layers 25 as viewed in the thickness direction z. In other words, the inner edge of each opening 13a and the inner edge of each opening 26a are located inside an outer edge 25a of a metal layer 25 as viewed in the thickness direction z. Note that the inner edge of each opening 13a may be located outside the outer edge 25a of a metal layer 25.

Each of the underlying layers 21 is provided between the wiring layer 14 and a metal layer 25. As viewed in the thickness direction z, the shape of each underlying layer 21 coincides with the shape of each metal layer 25. The underlying layers 21 are in contact with the wiring layer 14 via the openings 13a of the insulating layer 13 and the openings 26a of the surface protection film 26. As viewed in the thickness direction z, each of the underlying layers 21 overlaps with a portion of the surface protection film 26. Each of the underlying layers 21 includes a portion located between a metal layer 25 and the surface protection film 26. Each of the underlying layers 21 includes a first underlying layer 211 and a second underlying layer 212.

The first underlying layer 211 is in contact with the wiring layer 14 and the surface protection film 26. The first underlying layer 211 prevents the metal layer 25 from peeling off from the wiring layer 14 or the surface protection film 26. In the present embodiment, the first underlying layer 211 has a function as a mitigation layer that suppresses an influence of the orientation of the wiring layer 14 on the orientation of the metal layer 25. The first underlying layer 211 is made of a material having a unique orientation, and thus the material is less likely to be affected by the orientation of the wiring layer 14 than Ni, which is the material of the first layer 251 of the metal layer 25 located closest to the wiring layer 14. In the present embodiment, the first underlying layer 211 is made of TiW, for example. The first underlying layer 211 is formed by sputtering. Note that the material and formation method of the first underlying layer 211 are not particularly limited. Other examples of the material of the first underlying layer 211 include TiN and TaN.

The second underlying layer 212 is in contact with the first underlying layer 211, and is also in contact with the metal layer 25. The second underlying layer 212 serves as a conductive path for forming the metal layer 25 through electroplating. In the present embodiment, the second underlying layer 212 contains Cu, for example. The second underlying layer 212 is formed by sputtering. Note that the material and formation method of the second underlying layer 212 are not particularly limited.

As shown in FIGS. 6, 7, and 10, the reverse-surface electrode 24 is provided on the reverse surface 10b of the element body 10. The reverse-surface electrode 24 is provided over the entirety of the reverse surface 10b. The reverse-surface electrode 24 is electrically connected to the semiconductor layer 12 via the semiconductor substrate 11. The material and configuration of the reverse-surface electrode 24 are not particularly limited. For example, the reverse-surface electrode 24 includes a layer containing silver (Ag) and in contact with the semiconductor substrate 11 and a layer containing gold (Au) and formed on the Ag layer. As shown in FIGS. 6 and 7, the reverse-surface electrode 24 is bonded to the first lead 51 via a conductive bonding member 29. The material of the conductive bonding member 29 may be, but not limited to, solder, silver paste, or sintered silver.

The first lead 51 and the second leads 52 (hereinafter, also collectively referred to as a “conductive support member 5) support the semiconductor element A1 and serve as terminals used to mount the semiconductor device B1 onto a wiring board. The conductive support member 5 is formed by etching or stamping a metal plate, for example. The conductive support member 5 is made of a metal selected from Cu, Ni, iron (Fe), etc., or an alloy of Cu, Ni, or iron (Fe), for example. An appropriate portion of the conductive support member 5 may be plated with a metal selected from Ag, Ni, Pd, Au, etc. The thickness of the conductive support member 5 is not particularly limited, and may be 0.12 mm to 0.2 mm.

The first lead 51 supports the semiconductor element A1. The first lead 51 is electrically connected to the reverse-surface electrode 24 of the semiconductor element A1 via the conductive bonding member 29. As shown in FIGS. 2, 6, and 7, the first lead 51 has a die pad portion 511 and two extending portions 512.

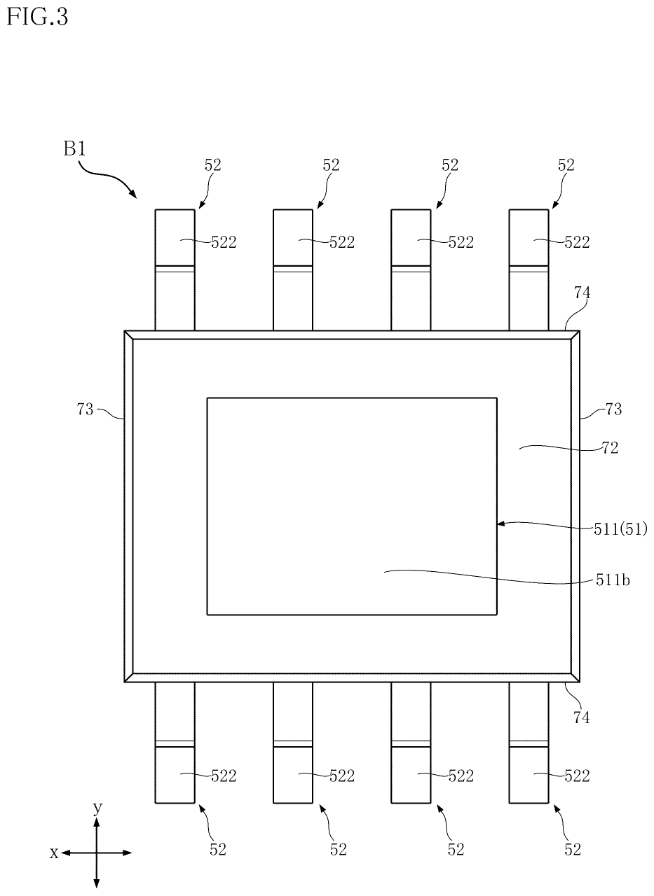

The die pad portion 511 supports the semiconductor element A1. The shape of the die pad portion 511 is not particularly limited. In the example shown in FIG. 2, the die pad portion 511 has a rectangular shape in plan view. As shown in FIGS. 6 and 7, the die pad portion 511 has a die-pad obverse surface 511a and a die-pad reverse surface 511b. The die-pad obverse surface 511a faces the first side in the thickness direction z. The die-pad reverse surface 511b faces away from the die-pad obverse surface 511a in the thickness direction z. In the illustrated example, the die-pad obverse surface 511a and the die-pad reverse surface 511b are flat surfaces. The semiconductor element A1 is bonded to the die-pad obverse surface 511a. As shown in FIGS. 3, 6, and 7, the die-pad reverse surface 511b is exposed from the sealing resin 7 (a resin reverse surface 72 described below).

As shown in FIGS. 2 and 6, the two extending portions 512 extend from the die pad portion 511 to the respective sides in the first direction x. In the example shown in FIG. 6, each of the extending portions 512 has a first section extending from the die pad portion 511 in the first direction x, a second section inclined relative to the first section and extending to the side in the thickness direction z that the die-pad obverse surface 511a faces, and a third section extending from the second section in the first direction x, so that the extending portion 512 has a bent shape as a whole.

As shown in FIG. 2, the second leads 52 are spaced apart from the first lead 51. The second leads 52 are arranged around the first lead 51. In the illustrated example, the second leads 52 include those arranged on a first side in the second direction y with respect to the first lead 51, and those arranged on a second side in the second direction y with respect to the first lead 51. The second leads 52 on each of the first side and the second side in the second direction y are spaced apart from each other in the first direction x. As shown in FIGS. 2 and 6, each of the second leads 52 has a pad portion 521 and a terminal portion 522.

One of the connecting members 6 is connected to the pad portion 521. In the example shown in FIG. 7, the pad portion 521 is offset from the die pad portion 511 to the side in the thickness direction z that the die-pad obverse surface 511a faces.

The terminal portion 522 extends outward from the pad portion 521 in the second direction y. The terminal portion 522 has a strip shape in plan view. As shown in FIG. 7, the terminal portion 522 is bent into a gull-wing shape as viewed in the first direction x. As shown in FIG. 7, a tip (a distal end far from the die pad portion 511 in the second direction y) of the terminal portion 522 is located at substantially the same position as the die pad portion 511 in the thickness direction z.

The terminal portions 522 of the second leads 52 are used as external terminals of the semiconductor device B1. The external terminals include an input terminal for a control signal, a ground terminal, an output terminal connected to a load, a power supply terminal, a non-connected terminal, and a self-diagnostic output terminal.

Each of the connecting members 6 electrically connects two elements that are spaced apart from each other. The connecting members 6 may be, but not limited to, bonding wires. The connecting members 6 contain Cu, for example. The material of the connecting members 6 is not particularly limited, and the connecting members 6 may contain Al or Au.

Each of the connecting members 6 is bonded to one of the metal layers 25 (pads) of the semiconductor element A1 and one of the pad portions 521 of the second leads 52. Each of the connecting members 6 electrically connects an internal circuit in the semiconductor element A1 and a second lead 52.

The sealing resin 7 covers a portion of each of the first lead 51 and the second leads 52, the semiconductor element A1, and the connecting members 6. The sealing resin 7 is an insulating resin, and may contain an epoxy resin mixed with a filler. The sealing resin 7 has a resin obverse surface 71, a resin reverse surface 72, two resin side surfaces 73, and two resin side surfaces 74.

The resin obverse surface 71 faces the same side as the die-pad obverse surface 511a in the thickness direction z. The resin obverse surface 71 is a flat surface, for example. The resin reverse surface 72 faces the opposite side from the resin obverse surface 71 (the same side as the die-pad reverse surface 511b) in the thickness direction z. The resin reverse surface 72 is a flat surface, for example. The die-pad reverse surface 511b is exposed from the resin reverse surface 72.

The two resin side surfaces 73 are located between the resin obverse surface 71 and the resin reverse surface 72 in the thickness direction z, and are spaced apart from each other in the first direction x as shown in FIGS. 2 to 4. Each of the extending portions 512 is exposed from one of the two resin side surfaces 73. The two resin side surfaces 74 are located between the resin obverse surface 71 and the resin reverse surface 72 in the thickness direction z, and are spaced apart from each other in the second direction y as shown in FIGS. 2, 3 and 5. Each of the second leads 52 protrudes from one of the two resin side surfaces 74.

The following describes the advantages of the semiconductor element A1 and the semiconductor device B1.

The semiconductor element A1 includes the first underlying layers 211 each provided between the wiring layer 14 and a metal layer 25. Each of the first underlying layers 211 is made of a material having a unique orientation, and thus the material is less likely to be affected by the orientation of the wiring layer 14 than Ni, which is the material of the first layer 251 of each metal layer 25 located closest to the wiring layer 14. In other words, the first underlying layer 211 has a function as a mitigation layer that suppresses an influence of the orientation of the wiring layer 14 on the orientation of the metal layer 25. As a result, the first layer 251 is less affected by the orientation of the wiring layer 14 when the first layer 251 grows by plating, thus allowing the semiconductor element A1 to suppress irregularities formed on a surface of the metal layer 25.

In the semiconductor element A1, the first underlying layer 211 is made of TiW. TiW has a unique orientation, and is less likely to be affected by the orientation of the wiring layer 14. Furthermore, TiW has high adhesion to the wiring layer 14 and the surface protection film 26. Thus, TiW is preferable as a material of the first underlying layer 211.

In the semiconductor element A1, the openings 26a of the surface protection film 26 are enclosed by the respective openings 13a of the insulating layer 13 as viewed in the thickness direction z. In contrast, if the openings 13a are enclosed by the openings 26a, cracks are likely to be formed in the insulating layer 13 at the positions overlapping with the openings 26a of the surface protection film 26 as viewed in the thickness direction z due to the thermal stress caused by the difference in coefficient of thermal expansion between the surface protection film 26 and the insulating layer 13. In the semiconductor element A1, however, the openings 26a are enclosed by the openings 13a to suppress the occurrence of cracks in the insulating layer 13.

Furthermore, in the semiconductor element A1, the openings 26a of the surface protection film 26 as viewed in the thickness direction z each have a circular shape similar to the shape of each opening 13a of the insulating layer 13. This allows the semiconductor element A1 to increase the contact area in which the underlying layers 21 make contact with the wiring layer 14 as compared to when the openings 26a each have a shape different from the shape of an opening 13a.

The semiconductor device B1 includes the semiconductor element A1. The semiconductor element A1 suppresses irregularities formed on a surface of each metal layer 25 (pad). This prevents a gap from being created between a metal layer 25 and a connecting member 6 bonded to the metal layer 25. As such, the semiconductor device B1 can reduce a bonding failure of a bonding wire, and thus has improved reliability.

Although the present embodiment has been described with an example where the metal layers 25, the openings 13a, and the openings 26a each have a rectangular shape as viewed in the thickness direction z, the present disclosure is not limited to this. The shape of each of the metal layers 25, the openings 13a, and the openings 13a as viewed in the thickness direction z is not particularly limited. Furthermore, the metal layers 25, the openings 13a, and the openings 26a preferably have similar shapes as viewed in the thickness direction z, but they may not have similar shapes. For example, only the shape of each metal layer 25 as viewed in the thickness direction z may have a circular shape.

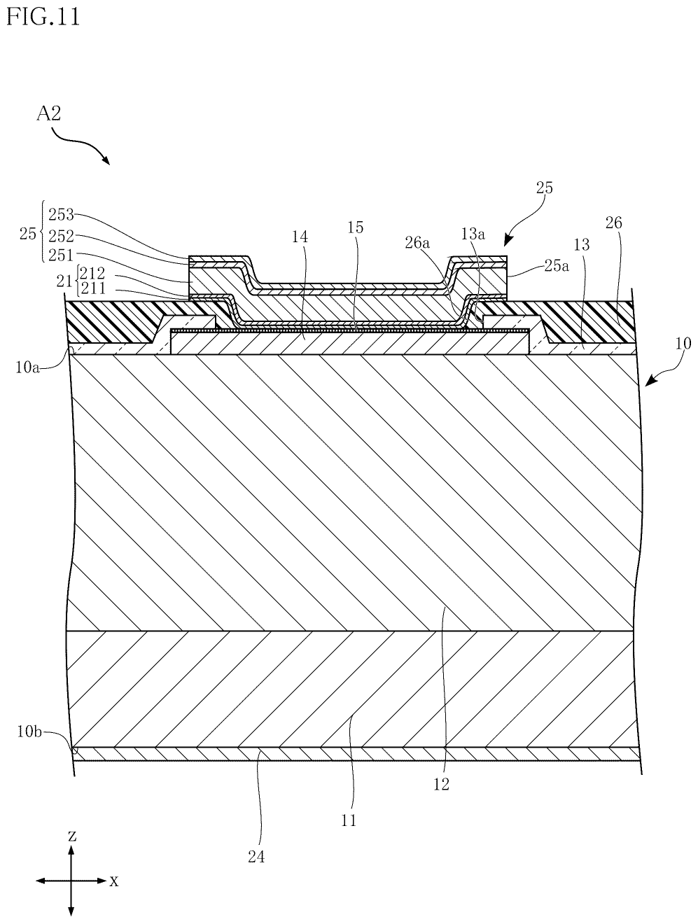

FIGS. 11 to 14 show other embodiments of the present disclosure. In these figures, elements that are the same as or similar to those in the above embodiment are provided with the same reference numerals as in the above embodiment.

### Second Embodiment

FIG. 11 is a view for describing a semiconductor element A2 according to a second embodiment of the present disclosure. FIG. 11 is a partially enlarged cross-sectional view showing the semiconductor element A2, and corresponds to FIG. 10. The semiconductor element A2 in the present embodiment is different from the semiconductor element in the first embodiment in further including a mitigation layer 15. The configurations and operations of other parts of the present embodiment are the same as those of the first embodiment.

In the present embodiment, each of the first underlying layers 211 is made of Ti, for example. In other words, each of the first underlying layers 211 is provided to prevent a metal layer 25 from peeling off from the wiring layer 14 or the surface protection film 26, and does not have a function as a mitigation layer. On the other hand, the semiconductor element A2 includes the mitigation layer 15 provided between the wiring layer 14 and each metal layer 25. The mitigation layer 15 is formed in contact with a surface (a surface that faces the same side as the obverse surface 10a of the element body 10) of the wiring layer 14 to cover the entirety of the surface of the wiring layer 14. The mitigation layer 15 includes a portion located between the wiring layer 14 and the insulating layer 13. Note that the mitigation layer 15 may not cover the entirety of the surface of the wiring layer 14, and may be formed to at least prevent the direct contact between the wiring layer 14 and each underlying layer 21. The mitigation layer 15 has a function of suppressing an influence of the orientation of the wiring layer 14 on the orientation of each metal layer 25. The mitigation layer 15 is made of a material having a unique orientation, and thus the material is less likely to be affected by the orientation of the wiring layer 14 than Ni, which is the material of the first layer 251 of each metal layer 25 located closest to the wiring layer 14. In the present embodiment, the mitigation layer 15 is made of TiN, for example. The mitigation layer 15 is formed by forming the wiring layer 14 on the obverse surface 10a and then sputtering on a surface of the wiring layer 14. Note that the material and formation method of the mitigation layer 15 are not particularly limited. Other examples of the material of the mitigation layer 15 include TiW and TaN.

According to the present embodiment, the semiconductor element A2 includes the mitigation layer 15 provided between the wiring layer 14 and each metal layer 25. The mitigation layer 15 is made of a material having a unique orientation, and thus the material is less likely to be affected by the orientation of the wiring layer 14 than the material of the first layer 251 of each metal layer 25 located closest to the wiring layer 14. In other words, the mitigation layer 15 suppresses an influence of the orientation of the wiring layer 14 on the orientation of each metal layer 25. As a result, the first layer 251 is less affected by the orientation of the wiring layer 14 when the first layer 251 grows by plating, thus allowing the semiconductor element A2 to suppress irregularities formed on a surface of the metal layer 25.

In the semiconductor element A2, the mitigation layer 15 is made of TiN. TiN has a unique orientation, and is less likely to be affected by the orientation of the wiring layer 14. Thus, TiN is preferable as a material of the mitigation layer 15. Furthermore, the semiconductor element A2 has advantages similar to the semiconductor element A1 owing to its common configuration with the semiconductor element A1.

### Third Embodiment

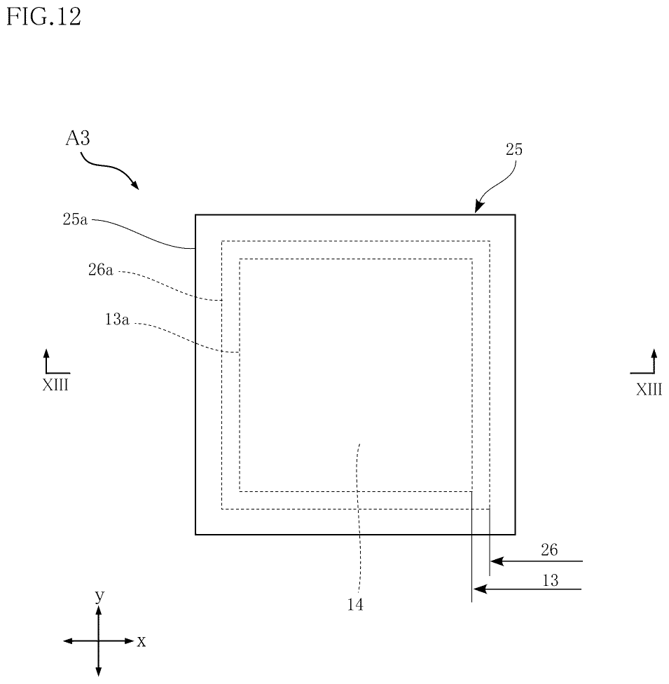

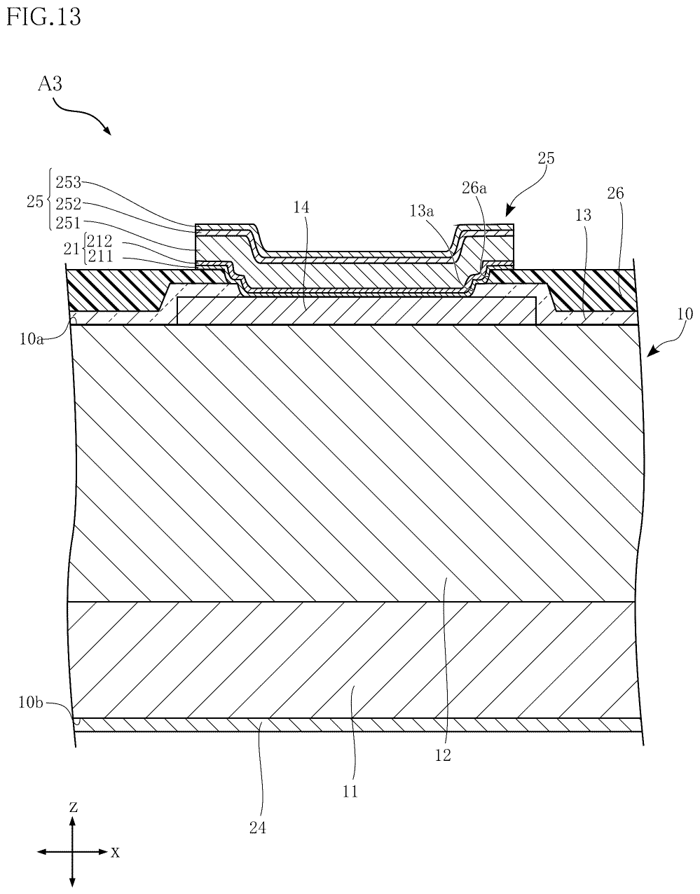

FIGS. 12 and 13 are views for describing a semiconductor element A3 according to a third embodiment of the present disclosure. FIG. 12 is a partially enlarged plan view showing the semiconductor element A3, and corresponds to FIG. 9. FIG. 13 is a cross-sectional view along line XIII-XIII in FIG. 12, and corresponds to FIG. 10. The semiconductor element A3 in the present embodiment is different from the semiconductor element in the first embodiment in that the openings 13a are enclosed by the openings 26a as viewed in the thickness direction z. The configurations and operations of other parts of the present embodiment are the same as those of the first embodiment. The present embodiment may be combined with any part of the first and second embodiments.

In the present embodiment, each of the first underlying layers 211 has a function as a mitigation layer that suppresses an influence of the orientation of the wiring layer 14 on the orientation of a metal layer 25. As a result, the first layer 251 is less affected by the orientation of the wiring layer 14 when the first layer 251 grows by plating, thus allowing the semiconductor element A3 to suppress irregularities formed on a surface of the metal layer 25. Furthermore, the semiconductor element A3 has advantages similar to the semiconductor element A1 owing to its common configuration with the semiconductor element A1. In the present embodiment, the openings 13a of the insulating layer 13 are enclosed by the respective openings 26a of the surface protection film 26 as viewed in the thickness direction z. In contrast, if the openings 26a are enclosed by the openings 13a, cracks are likely to be formed in the surface protection film 26 at the positions overlapping with the openings 13a of the insulating layer 13 as viewed in the thickness direction z due to the thermal stress caused by the difference in coefficient of thermal expansion between the surface protection film 26 and the insulating layer 13. In the semiconductor element A3, however, the openings 13a are enclosed by the openings 26a to suppress the occurrence of cracks in the surface protection film 26.

### Fourth Embodiment

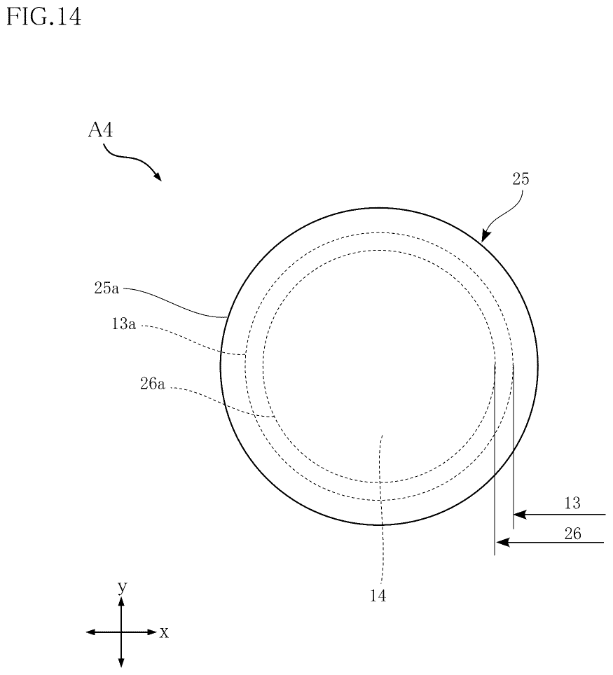

FIG. 14 is a view for describing a semiconductor element A4 according to a fourth embodiment of the present disclosure. FIG. 14 is a partially enlarged plan view showing the semiconductor element A4, and corresponds to FIG. 9. The semiconductor element A4 in the present embodiment is different from the semiconductor element in the first embodiment in that each of the metal layers 25 and the underlying layers 21 has a circular shape as viewed in the thickness direction z. The configurations and operations of other parts of the present embodiment are the same as those of the first embodiment. The present embodiment may be combined with any part of the first to third embodiments.

In the present embodiment, each of the metal layers 25 and the underlying layers 21 has a circular shape as viewed in the thickness direction z. Furthermore, in the present embodiment, each of the openings 13a of the insulating layer 13 and the openings 26a of the surface protection film 26 also has a circular shape as viewed in the thickness direction z.

In the present embodiment, each of the first underlying layers 211 has a function as a mitigation layer that suppresses an influence of the orientation of the wiring layer 14 on the orientation of a metal layer 25. As a result, the first layer 251 is less affected by the orientation of the wiring layer 14 when the first layer 251 grows by plating, thus allowing the semiconductor element A4 to suppress irregularities formed on a surface of the metal layer 25. Furthermore, the semiconductor element A4 has advantages similar to the semiconductor element A1 owing to its common configuration with the semiconductor element A1.

In the present embodiment, each of the metal layers 25 and the underlying layers 21 has a circular shape as viewed in the thickness direction z. As viewed in the thickness direction z, each of the metal layers 25 and the underlying layers 21 overlaps with a portion of the surface protection film 26. The metal layers 25 and the underlying layers 21 have coefficients of thermal expansion different from that of the surface protection film 26 due to the difference in material, and thus thermal stress is applied to the surface protection film 26. When each of the metal layers 25 and the underlying layers 21 has a rectangular shape as viewed in the thickness direction z, thermal stress is concentrated at the positions of the surface protection film 26 that overlap with the corners of the metal layer 25 and the underlying layer 21 as viewed in the thickness direction z, thus easily causing cracks at the positions. However, in the semiconductor element A4, each of the metal layers 25 and the underlying layers 21 has a circular shape as viewed in the thickness direction z, which allows thermal stress to be dispersed and not concentrated in a particular area. Thus, the semiconductor element A4 can suppress the occurrence of cracks in the surface protection film 26, as compared to when the shape of each of the metal layers 25 and the underlying layers 21 is rectangular as viewed in the thickness direction z.

In the semiconductor element A4, the openings 26a of the surface protection film 26 are enclosed by the respective openings 13a of the insulating layer 13 as viewed in the thickness direction z. Furthermore, although the surface protection film 26 is subjected to thermal stress due to the difference in coefficient of thermal expansion between the insulating layer 13 and the surface protection film 26, the thermal stress is dispersed and not concentrated in a particular area because the openings 13a each have a circular shape as viewed in the thickness direction z. Thus, the semiconductor element A4 can suppress the occurrence of cracks in the surface protection film 26, as compared to when the shape of each opening 13a is rectangular as viewed in the thickness direction z.

Although the first to fourth embodiments have been described with an example where the semiconductor elements A1 to A4 are LSIs, the present disclosure is not limited to this. The semiconductor elements A1 to A4 may be discrete semiconductor elements. Furthermore, the mode (type) of the semiconductor device B1 is not limited.

The semiconductor element and the semiconductor device according to the present disclosure are not limited to the above embodiments. Various design changes can be made to the specific configurations of the components in the semiconductor element and the semiconductor device according to the present disclosure. The present disclosure includes the embodiments described in the following clauses.

### Clause 1

A semiconductor element (A1) comprising:
an element body (10) including an element obverse surface (10a) facing a first side in a thickness direction;
a wiring layer (14) formed on the element obverse surface and electrically connected to the element body;
an insulating layer (13) covering the element obverse surface and the wiring layer, and including a first opening (13a) overlapping with the wiring layer as viewed in the thickness direction;
a surface protection film (26) covering the insulating layer, and including a second opening (26a) overlapping with the wiring layer and the first opening as viewed in the thickness direction;
a metal layer (25) overlapping with the first opening and the second opening, and also overlapping with the surface protection film as viewed in the thickness direction, and a mitigation layer (21) provided between the wiring layer and the metal layer,
wherein a first material of the mitigation layer is less affected by an orientation of the wiring layer than a second material of a portion (251) of the metal layer located closest to the wiring layer.

### Clause 2

The semiconductor element according to clause 1, wherein the wiring layer contains Al.

### Clause 3

The semiconductor element according to clause 1 or 2, wherein the mitigation layer includes a portion located between the metal layer and the surface protection film.

### Clause 4

The semiconductor element according to clause 3, wherein the first material contains TiW.

### Clause 5

The semiconductor element according to clause 1 or 2, wherein the mitigation layer includes a portion located between the wiring layer and the insulating layer.

### Clause 6

The semiconductor element according to clause 5, wherein the first material contains TiN.

### Clause 7

The semiconductor element according to any of clauses 1 to 6, wherein the metal layer includes:
a first layer (251) containing Ni; and
a second layer (252) in contact with a surface of the first layer on a side that the element obverse surface faces, and containing Pd.

### Clause 8

The semiconductor element according to clause 7, wherein the metal layer further includes a third layer (253) in contact with a surface of the second layer on the side that the element obverse surface faces, and containing Au.

### Clause 9

The semiconductor element according to any of clauses 1 to 8, wherein the metal layer has a circular shape as viewed in the thickness direction.

### Clause 10

The semiconductor element according to any of clauses 1 to 9, wherein a shape of the first opening and a shape of the second opening are each similar to a shape of the metal layer as viewed in the thickness direction.

### Clause 11

The semiconductor element according to any of clauses 1 to 10, wherein the second opening is enclosed by the first opening as viewed in the thickness direction.

### Clause 12

The semiconductor element according to any of clauses 1 to 11, wherein the surface protection film contains polyimide resin.

### Clause 13

The semiconductor element according to any of clauses 1 to 12, further comprising a reverse-surface electrode (24) electrically connected to the element body,
wherein the element body includes an element reverse surface (10b) facing away from the element obverse surface in the thickness direction, and
the reverse-surface electrode is arranged on the element reverse surface.

### Clause 14

A semiconductor device (B1), comprising:
the semiconductor element according to any of clauses 1 to 13;
a conductive support member (5) supporting the semiconductor element and electrically connected to the semiconductor element;
a connecting member (6) bonded to the metal layer of the semiconductor element and the conductive support member; and
a sealing resin (7) covering the semiconductor element, the connecting member, and a portion of the conductive support member.

### Clause 15

The semiconductor device according to clause 14, wherein the connecting member is a bonding wire containing Cu.

### REFERENCE NUMERALS

A1 to A4: Semiconductor element B1: Semiconductor device
10: Element body 10a: Obverse surface
10b: Reverse surface 11: Semiconductor substrate
12: Semiconductor layer 13: Insulating layer
13a: Opening 14: Wiring layer
15: Mitigation layer 24: Reverse-surface electrode
25: Metal layer 25a: Outer edge
251: First layer 252: Second layer
253: Third layer 21: Underlying layer
211: First underlying layer 212: Second underlying layer
26: Surface protection film 26a: Opening
29: Conductive bonding member 5: Conductive support member
51: First lead 511: Die pad portion
511a: Die-pad obverse surface 511b: Die-pad reverse surface
512: Extending portion 52: Second lead
521: Pad portion 522: Terminal portion
6: Connecting member 7: Sealing resin
71: Resin obverse surface 72: Resin reverse surface
73: Resin side surface 74: Resin side surface

1. A semiconductor element comprising:
an element body including an element obverse surface facing a first side in a thickness direction;
a wiring layer formed on the element obverse surface and electrically connected to the element body;
an insulating layer covering the element obverse surface and the wiring layer, and including a first opening overlapping with the wiring layer as viewed in the thickness direction;
a surface protection film covering the insulating layer, and including a second opening overlapping with the wiring layer and the first opening as viewed in the thickness direction;
a metal layer overlapping with the first opening and the second opening, and also overlapping with the surface protection film as viewed in the thickness direction, and
a mitigation layer provided between the wiring layer and the metal layer,
wherein a first material of the mitigation layer is less affected by an orientation of the wiring layer than a second material of a portion of the metal layer located closest to the wiring layer.

2. The semiconductor element according to claim 1, wherein the wiring layer contains Al.

3. The semiconductor element according to claim 1, wherein the mitigation layer includes a portion located between the metal layer and the surface protection film.

4. The semiconductor element according to claim 3, wherein the first material contains TiW.

5. The semiconductor element according to claim 1, wherein the mitigation layer includes a portion located between the wiring layer and the insulating layer.

6. The semiconductor element according to claim 5, wherein the first material contains TiN.

7. The semiconductor element according to claim 1, wherein the metal layer includes:
a first layer containing Ni; and
a second layer in contact with a surface of the first layer on a side that the element obverse surface faces, and containing Pd.

8. The semiconductor element according to claim 7, wherein the metal layer further includes a third layer in contact with a surface of the second layer on the side that the element obverse surface faces, and containing Au.

9. The semiconductor element according to claim 1, wherein the metal layer has a circular shape as viewed in the thickness direction.

10. The semiconductor element according to claim 1, wherein a shape of the first opening and a shape of the second opening are each similar to a shape of the metal layer as viewed in the thickness direction.

11. The semiconductor element according to claim 1, wherein the second opening is enclosed by the first opening as viewed in the thickness direction.

12. The semiconductor element according to claim 1, wherein the surface protection film contains polyimide resin.

13. The semiconductor element according to claim 1, further comprising a reverse-surface electrode electrically connected to the element body,
wherein the element body includes an element reverse surface facing away from the element obverse surface in the thickness direction, and
the reverse-surface electrode is arranged on the element reverse surface.

14. A semiconductor device, comprising:
the semiconductor element according to claim 1;
a conductive support member supporting the semiconductor element and electrically connected to the semiconductor element;
a connecting member bonded to the metal layer of the semiconductor element and the conductive support member; and
a sealing resin covering the semiconductor element, the connecting member, and a portion of the conductive support member.

15. The semiconductor device according to claim 14, wherein the connecting member is a bonding wire containing Cu.
